(19) United States
(12) Patent Application Publication
(10) Pub. No.: US 2026/0146576 A1
(43) Pub. Date: May 28, 2026

(54) Bypass Circuit Board

(71) Applicant: Maks Enterprises LLC, Chatsworth, CA (US)

(72) Inventor: Mechael M Cabessa, Chatsworth, CA (US)

(21) Appl. No.: 18/955,998

(22) Filed: Nov. 22, 2024

(51) Int. Cl. F02M 37/00; B60R 16/023; F02M 37/08; H05K 1/14; H05K 1/18

(52) U.S. Cl. CPC F02M 37/0011; B60R 16/0231; F02M 37/08; F02M 2037/085; H05K 1/181; H05K 2201/10053; H05K 2201/10166

(57) ABSTRACT

A vehicle fuel pump power management circuit that replaces traditional relay and fuse-based power routing with a MOSFET-based circuit controlled by the Automatic Shutdown Relay (ASD) and Engine Control Unit (ECU). The MOSFET circuit allows direct current flow from the vehicle's power supply to the fuel pump, enhancing reliability by reducing mechanical failures associated with conventional relays. A multi-layered PCB design minimizes electromagnetic interference, enhances heat dissipation, and prevents component overheating, while isolating circuits for optimized performance. The ECU provides real-time adjustments based on sensor feedback, ensuring efficient fuel injection timing.

### SUMMARY

To understand the utility of the bypass circuit board, it is important to consider a vehicle's various components and their operation.

The car's ignition system, including the ignition switch, the ignition coil, and the spark plugs, is responsible for initiating and maintaining operation of the car's engine by generating a spark. The ignition switch, actuated by the driver by turning a key or pushing a start button, controls the car's electrical power across several positions: OFF, ACC (accessory), ON, and START. In the OFF position, all circuits are open, and no power flows to the vehicle's electrical system. In the ACC position, some circuits are closed, enabling power to flow to certain vehicle accessories, such as the radio. By manipulating the switch into the ON position, most of the vehicle's circuits are closed, thereby providing power. Such powered circuits include the engine control unit (ECU), the ignition system, and the fuel injection system. Further manipulating the switch into the START position initiates engine cranking and consequently voltage conversion by the ignition coil (in the ignition system) via electromagnetic induction. Converting low voltage to high voltage creates the spark in the spark plugs, which causes ignition, which in turn causes combustion. Combustion is the controlled explosion which exerts force on the pistons, thereby creating the mechanical energy necessary for driving the engine.

More specifically, current from the battery (when the ignition is on the ON position) flows through the primary winding part of the ignition coil, creating a magnetic field (which is further enhanced by the ignition coil's iron core). This magnetic field is disrupted when a switch in the circuit is activated. Changing the ignition switch to the START position signals the engine control unit (ECU) to activate a transistor disposed on the ignition coil circuit. The transistor, in turn, interrupts the current to the primary coil, thereby causing a collapse of the magnetic field—this sudden collapse triggers an electromotive force (EMF), which induces a high voltage in the secondary winding part of the ignition coil. This high voltage in turn overcomes the resistance in the air gap in the spark plug, allowing a spark to jump across the air gap and ignite the fuel-air (combustion) mixture in the combustion chamber. Thus, the spark leads to ignition, which then leads to combustion.

12V DC power is supplied initially by the battery in order to start the engine and the power systems before the engine is running, but once the engine is running, the alternator converts the engine's mechanical energy into electricity. This electricity is used not only to recharge the battery, but also to provide electricity to the vehicle's electrical systems, including the fuel injection system, directly from the alternator. The electricity (i.e., power) from the alternator is more stable and continuous than the electricity from the battery, ensuring a consistent voltage supply that is crucial for optimal performance and durability of the electrical components. The battery then serves primarily to provide backup and supplemental power to the fuel injection system when the electrical load exceeds the alternator's capacity.

Occasionally, the alternator may produce atypically low voltage, which may be sufficient for various relatively less sensitive components, such as the lights or audio system, but such low voltage may be inadequate for the fuel injection system. Low voltage directed to the fuel injection system may occur when other components, such as HVAC systems, heated seats, etc., are imposing too high of a demand on the alternator. In such instances, low power from the alternator may be buffered by obtaining power from the battery.

The fuel injection necessary to create the fuel-air mixture of the combustion chamber is initiated not by the ignition system, but by the engine control unit (ECU). When the ignition switch is changed to the ON position, several circuits are closed, enabling power to flow from the battery to the ECU. Once powered, the ECU performs a series of system checks by analyzing various vehicle and engine sensors, including the mass air flow (MAF) sensor; oxygen sensors, crankshaft and camshaft position sensors, a throttle position sensor, an engine coolant temperature sensor, and manifold absolute pressure (MAP) sensor. Based on the sensor data, the ECU determines the timing and duration of the fuel injection pulses in order to optimize the combustion efficiency throughout the engine cycle.

The two most common types of fuel injection systems include port fuel injection (PFI), in which injectors spray fuel into the intake manifold just before the intake valves, and direct fuel injection (DI), in which injectors convey fuel directly into the combustion chamber of each cylinder. In each case, fuel is supplied to the injectors from the fuel tank via fuel pumps.

A fuel injector comprises an electromagnetic coil (a solenoid), a ferromagnetic plunger, a spring, a fuel inlet, a nozzle, and a valve. When the ECU activates (i.e., energizes) the solenoid via an electrical signal, the energized solenoid generates an electromagnetic field, which engages the plunger. Upon engagement, the plunger moves the valve to open the nozzle. Fuel, pressurized by the fuel pump, is then forced through the nozzle into the combustion chambers. When the ECU deactivates (i.e., de-energizes) the solenoid, the spring exerts a force to return the plunger to its original position, thereby closing the nozzle.

The fuel pump fuse, fuel pump relay, and fuel pump are closely related components essential in ensuring the engine receives adequate fueling.

The power to the fuel pumps is controlled by a fuel pump relay. Specifically, the fuel pump relay enables or disables the flow of power from the battery-at least initially-to the fuel pump's electric motor, which in turn drives the fuel pump's pump mechanism (e.g., a turbine, rotor, or diaphragm) responsible for physically pumping the fuel through the fuel lines toward the engine. The fuel pump relay is itself controlled by the ECU. In some systems, the ECU can control the speed of the fuel pump by varying the power supplied to it.

A fuel pump relay consists of an electromagnetic coil, a set of mechanical contacts for opening and closing the circuit supplying power to the fuel pump, and a spring for shifting the mechanical contacts between their opening and closing configurations. When the relay coil is energized, it creates a magnetic field that pulls the contacts together, closing the circuit and allowing power to flow to the fuel pump. When the coil is de-energized, the spring forces the contacts apart, opening the circuit and cutting off the power supply to the fuel pump.

The fuel pump fuse serves as a safeguard by acting as an intermediary between the fuel pump and the power source to protect the fuel pump against excess current, which may be caused by a short circuit within the wiring or components upstream or downstream of the fuse, such as poor grounding, or even by poor connections or damaged wires within the fuel pump itself. Excess current can damage the fuel pump by causing overheating and potentially even causing a fire or explosion, leading to costly repairs. To protect the fuel pump, from excess current, the fuel pump fuse will blow, thus cutting power to the fuel pump. Heat is generated as current passes through the metal strip or wire within, and excess current increases this heat. When the heat exceeds the melting point of the metal strip or wire, the metal strip or wire melts, thus resulting in a blown fuse. A blown fuse cannot conduct electricity, thereby protecting the fuel pump from further damage. The fuel pump fuse also indirectly protects the fuel pump fuse by preventing overloads or faults in the circuit downstream.

In many vehicles, the fuel pump relay has its own dedicated fuse, which safeguards the fuel pump relay in the same way that the fuel pump fuse safeguards the fuel pump.

The fuel pump relay, the fuel pump relay fuse, and the fuel pump fuse are generally located in the vehicle's main fuse box while the fuel pump is typically located inside the fuel tank or very close to it.

The automatic shutdown relay (ASD) operates as a broader safety mechanism by managing the power supply to various critical engine components, including the ignition coils and the fuel injection system. Specifically, the ASD shuts off the power supply under certain conditions.

Initially, when the ignition is on the ON position, the ECU activates the ASD relay (via a resistor within the ASD relay circuit), which then allows power to be supplied to the fuel pump and fuel injectors. The ASD relay continues to enable the power supply so long as the ECU is receiving signals that the engine is running properly. If the ECU loses signal from, for example, the crankshaft position sensor within the engine, the ECU deactivates the ASD relay, which then cuts power to the ignition coils and the fuel injection system.

Thus, while the ECU manages the operational details of the fuel injection system, the ASD relay controls its power supply. The ASD relay is not merely a passive power cutoff device, but actively enables the flow of power to the fuel injection system. Initially, the ASD relay is itself powered by the battery when the ignition is turned on. Once the engine starts (i.e., when ignition is in the START position and then released back into the ON position), the alternator takes over as the primary power source, continuing to supply power to the ASD relay and thereby to the fuel injection system. Whether power is derived directly from the battery or the alternator, it passes into the ASD relay into the fuel injection system. The ASD relay is generally not activated when ignition is in the ACC position as it is linked specifically to engine control functions.

In normal vehicular operation, the ECU operationally controls the fuel pump (via the fuel pump relay) and fuel injectors (via the solenoids). When the ignition is turned on, the fuel pump and the fuel injectors are initially powered by the battery through the fuel pump relay and the solenoids. Once the engine starts, the alternator takes over and supplies power to the fuel pump relay, and consequently to the fuel pump itself, as well as the solenoids that control the fuel injectors. The entire power supply is protected by the fuel pump fuse.

Fuel pump relay malfunctions may cause problems in the starting and running of the engine, and there are several ways in which fuel pump relay malfunctions may occur. As a first example, the relay's switch may remain open, thereby denying the fuel pump the power it needs to supply fuel to the fuel injectors. This type of malfunction may be caused by worn-out contacts, a failed coil, or electrical faults within the relay. As a second example, the relay's switch remains closed, therefore causing the fuel pump to operate continuously, even when the engine is off—this can drain the battery and cause the fuel pump to wear out prematurely. This type of malfunction may be caused by fused contacts or a mechanical failure within the relay.

As a third example, poor wiring, internal damage to the relay, or loose relay terminals may result in erratic powering of the fuel pump. Erratic fuel pump operations may lead to poor engine performance, including power loss, stalling, and difficulty starting. As a fourth example, damage to the electromagnetic coil within the relay, due to overvoltage, overheating, or natural wear and tear, may prevent the relay from activating.

As a fifth example, repetitive switching on and off of the relay causes a carbon build-up between the relay contacts. Specifically, a spark occurs between the contacts each time they open or close. Carbon deposits are a byproduct of the sparking process, and the repeated sparking may result in excessive carbon buildup impeding the conductivity between the contacts. This problem is especially prevalent in relays designed to handle high current loads or relays having poorly designed or manufactured contacts.

In addition to these examples, there are many other possible causes of relay failure, including exposure to extreme temperatures, moisture, and excessive vibrations.

In order to remedy fuel pump relay malfunctions, the fuel pump relay must often be replaced. In order to do this, the battery must be disconnected to prevent any accidental shorts or other electrical issues, the fuse box cover must be removed to gain access to the relays, and the relays must be removed, with care being needed to avoid damaging the socket or any surrounding relays and fuses. Then the new relay must be installed, and the battery must be reconnected (and tested). Finally, the fuse box cover must be placed back on the fuse box. Potentials problems here may include misidentification of the fuel pump relay with some other relay, damage to the socket, pins, or other components when removing or installing the relay, or inserting the relay in the wrong direction or not fully seating it in the socket.

In lieu of replacing the fuel pump relay, the fuel pump relay fuse, or the fuel pump fuse with new versions of the same components, the bypass circuit board described here may be installed instead.

This bypass circuit board bypasses these components, directly routing power to the fuel pump's electric motor. The bypass circuit board is configured via specific wiring and terminals to ensure power transmission, while operational control over this power remains with the ECU based on ECU processing of sensor data.

Power through the bypass circuit board is controlled by the ASD relay, which actively enables the flow of power and also serves as a power cutoff device in response to signals from the ECU. The ASD relay and the bypass circuit board act as intermediaries through which power from the battery or alternator is conveyed to the fuel pump, however the ASD relay serves as a prior intermediary to the bypass circuit board. Since the ASD does not receive power when the ignition is in the ACC position, the bypass circuit board similarly does not receive power during this state, and consequently, such power is not supplied to the fuel pump. In addition to directing power toward the fuel pump, the bypass circuit board itself may be powered by the battery or alternator.

Specifically, the bypass circuit board utilizes an automatic switch toggled by the ASD relay in response to ECU signals—it is this automatic switch that controls the flow of power to the fuel pump, supplanting the role previously played by the fuel pump relay. The coupling of an N-channel and P-channel MOSFETS, as will be described below, may comprise the bypass circuit board switch.

The bypass circuit board comprises ICs (integrated circuits) and MOSFETs (metal-oxide semiconductor field-effect transistors).

These ICs may include build-in protection features to prevent damage from short circuits, such as overcurrent protection or thermal shutdown features. Additionally, the ICs may include dedicated fuses, breakers, or other protective devices. The MOSFETs may be integrated with current-sensing resistors that are configured to detect excessive current flow and shut off in the presence thereof. The MOSFETs may similarly include temperature sensing circuits that shut off the MOSFETs if overheating. Such features obviate the need for the fuel pump relay fuse and the fuel pump fuse. The bypass circuit board may comprise fuse-replacement mechanisms dedicated to replacing the fuel pump relay fuse and the fuel pump fuse.

The MOSFETs may include both N-channel MOSFETS, which use electron flow as the charge carrier, and P-channel MOSFETs, which use hole flow as the charge carrier. Both types of MOSFETs comprise three types of terminals: source terminals through which current enters the MOSFET, drain terminals through which current exits the MOSFET, and gate terminals which control the conductivity of the channel between the source and drain terminals. Specifically, the voltage applied to the gate terminal creates an electric field to modulate carrier concentration (i.e., the number of charge carriers—whether electrons or holes—per unit volume within the channel). Gate terminals are electrically isolated from the channel between the source and drain via a layer of insulating material, such as silicon dioxide.

Electron flow charge carriers are the particles (i.e., electrons) that carry electric charge and enable current flow through the device when voltage is applied to the gate terminal. The use of electron flow charge carriers in N-channel MOSFETs enable better performance characteristics like switching speeds and lower conduction losses. Specifically, the high mobility of electrons results in a lower on-resistance when compared to hole flow charge carrying. On-resistance refers to the resistance between the drain and source terminals.

Lower on-resistance results in lower power dissipation when current flows through the N-channel MOSFETs, thereby reducing heat generation and improving efficiency. The lower on-resistance of N-channel MOSFETs are due to their larger channel area for current flow, which in turn is due to the electron mobility.

Hole carriers are essentially the positions (i.e., holes) formerly occupied by electrons in a material's crystal lattice after the an (excited) electron leaves. Thus, the holes are electrically positive due to the absence of the electrons. As electrons move to fill in the positively charged holes, new holes from those same electrons are created. Thus, figuratively speaking, a movement of holes could be said to occur, although in actuality only the electrons are literally moving. When voltage is applied to the gate in P-channel MOSFETs, the hole concentration is modulated in a channel, allowing current to flow between the source and the drain.

N-channel MOSFETs are typically used for low-side switching applications and P-channel MOSFETs are typically used for high-side switching applications. Side-switching refers to the placement of the MOSFET in a circuit relative to the load and power supply. In high-side switching applications, the switch (e.g., the MOSFET) is placed between the power supply and the load (i.e., the components that consume electrical power). When the MOSFET is closed, it connects the load to the power supply. In low-side switching applications, the load is connected to the power supply directly, with the MOSFET positioned as an intermediary between the load and the ground.

High-side switching applications require more complex gate driver circuitry in N-channel MOSFETs because they require a gate voltage higher than the supply voltage to turn on the N-channel MOSFETs. Conversely, P-channel MOSFETs can be actuated by pulling the gate voltage below the source voltage (i.e., the voltage supplied by the power source), which enables use of the P-channel MOSFETs in high-side switching applications where the load is directly connected to ground.

The ASD relay is connected to the N-channel MOSFET via the N-channel gate terminal. When the ASD relay provides a voltage signal (typically a positive voltage relative to the source terminal), it activates the N-channel MOSFET. This activation allows current, which consists of negative charge carriers (electrons), to flow from the N-channel source terminal to the N-channel drain terminal. While electrons flow from source to drain, the conventional current direction is considered to be from drain to source. The N-channel gate terminal induces this current flow by modulating the electric field in the channel between the source and drain terminals, enabling current flow when a sufficient gate-to-source voltage (VGSV_{GS}VGS) is applied.

The N-channel MOSFET circuit then applies a lower voltage (relative to the P-channel source) to the P-channel MOSFET gate terminal. The P-channel gate terminal induces current flow in the P-channel MOSFET circuit by modulating the electric field in the channel between the P-channel source and drain terminals. This action enables positive charge carrier current (holes) to flow from the P-channel source terminal to the P-channel drain terminal. This current is used to power the fuel pump electric motor.

When the ASD relay ceases to enable power flow to the N-channel gate terminal, the N-channel MOSFET turns off and the N-channel drain terminal ceases its application of voltage to the p-channel gate terminal; then, the P-channel MOSFET turns off and the P-channel drain terminal ceases powering the fuel pump electric motor. The bypass circuit board may comprise a grounding wire connected to the vehicle chassis. Grounding points may include screws or bolts on the chassis, with attachment provided thereto via a ring terminal. In one version, the bypass circuit board may be grounded via a ground plane, which is itself connected, either via direct contact or via the grounding wire, to the chassis.

The bypass circuit board may comprise a series of printed circuit boards (PCBs). Specifically, the bypass circuit board may comprise four separate PCBs, with each PCB having a dedicated set of parts and intended for a particular, mutually beneficial purpose. Having a plurality of PCBs helps isolate circuits to prevent electromagnetic interference, thereby enhancing the performance of the sensitive on-board components, damper vibration shock, distribute components to better manage heat dissipation and prevent overheating, facilitate repair and maintenance, optimize space, and reduce manufacturing costs. The PCB's may include MID1B, MID2B, and TOP PCB, which are not in direct contact with the bottommost PCB.

The PCBs may comprise a number of structural mechanisms to maintain their fixed positions vis-á-vis the vehicular components. These mechanisms may include fitting holes in the PCBs with mounting bosses attached to vehicular components. The bypass circuit board may also include a protective enclosure to shield it from dust and debris. The protective enclosure may be heat and water resistant to prevent corrosion, wear, and tear. The role of the protective enclosure may be satisfied by that if the TIPM. In one version, the bypass circuit board may be disposed in a plug cavity of a TIPM (Totally Integrated Power Module) beneath the C5 brown plug.

### BRIEF DESCRIPTION OF THE DRAWINGS

FIG. 1 shows a system process of a normal vehicle with a normally operating ASD relay, ECU, battery, alternator, fuel pump, fuel pump relay, fuel pump fuse, and fuel pump relay fuse, fuel pump injectors, fuel tank, and combustion chamber.

FIG. 2. shows a normal vehicle's ignition process.

FIG. 3 shows a normal vehicle's ignition to combustion process.

FIG. 4 shows a normal vehicle's fuel injection process.

FIG. 5 shows the flow of power from the ECU to the fuel pump motor and the pumping of fuel to the fuel lines.

FIG. 6 shows a system process of the ASD's control over ignition and the fuel injection system.

FIG. 7 shows a system control architecture of the bypass circuit, the ASD, the ECU, and the fuel pump motor.

FIG. 8 shows a system architecture of current flow pertaining to the ASD relay, MOSFETs, and fuel pump motor.

FIG. 9 shows an exemplary bypass circuit board.

### DETAILED DESCRIPTION

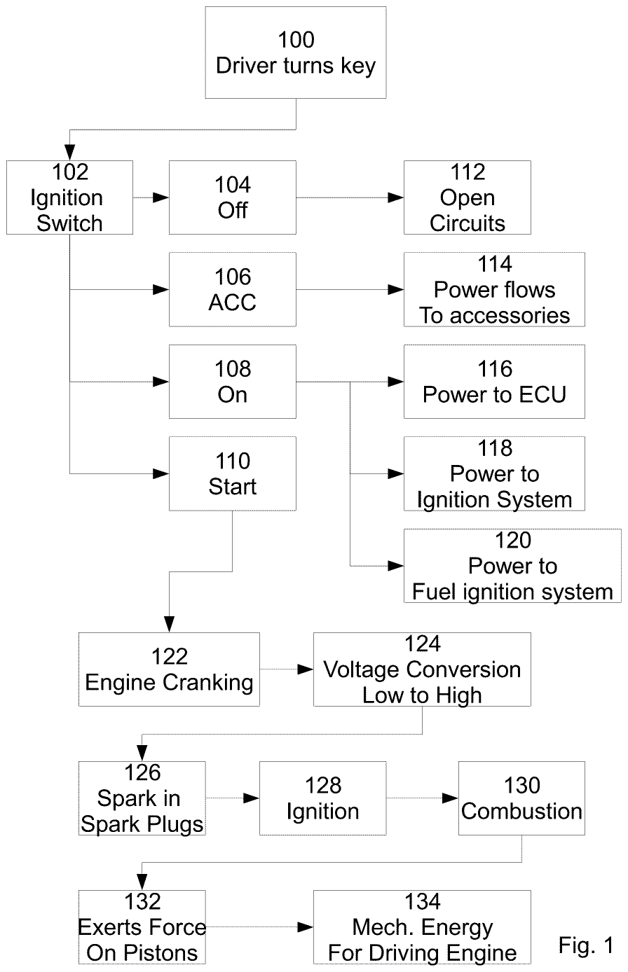

FIG. 1 shows system architecture of a normal vehicle with a normally operating ASD relay, ECU, battery, alternator, fuel pump, fuel pump relay, fuel pump fuse, and fuel pump relay fuse, fuel pump injectors, fuel tank, and combustion chamber. The car's ignition system, including the ignition switch, the ignition coil, and the spark plugs, is responsible for initiating and maintaining operation of the car's engine by generating a spark. The ignition switch 102, actuated by the driver by turning a key 100 or pushing a start button, controls the car's electrical power across several positions: OFF 104, ACC (accessory) 106, ON 108, and START 110. In the OFF position, all circuits are open 112, and no power flows to the vehicle's electrical system. In the ACC position, some circuits are closed, enabling power to flow 114 to certain vehicle accessories, such as the radio. By manipulating the switch into the ON position, most of the vehicle's circuits are closed, thereby providing power. Such powered circuits include the engine control unit (ECU) 116, the ignition system 118, and the fuel injection system 120. Further manipulating the switch into the START position initiates engine cranking 122 and consequently voltage conversion 124 by the ignition coil (in the ignition system) via electromagnetic induction. Converting low voltage to high voltage 124 creates the spark in the spark plugs 126, which causes ignition 128, which in turn causes combustion 130. Combustion is the controlled explosion which exerts force on the pistons 132, thereby creating the mechanical energy necessary for driving the engine 134.

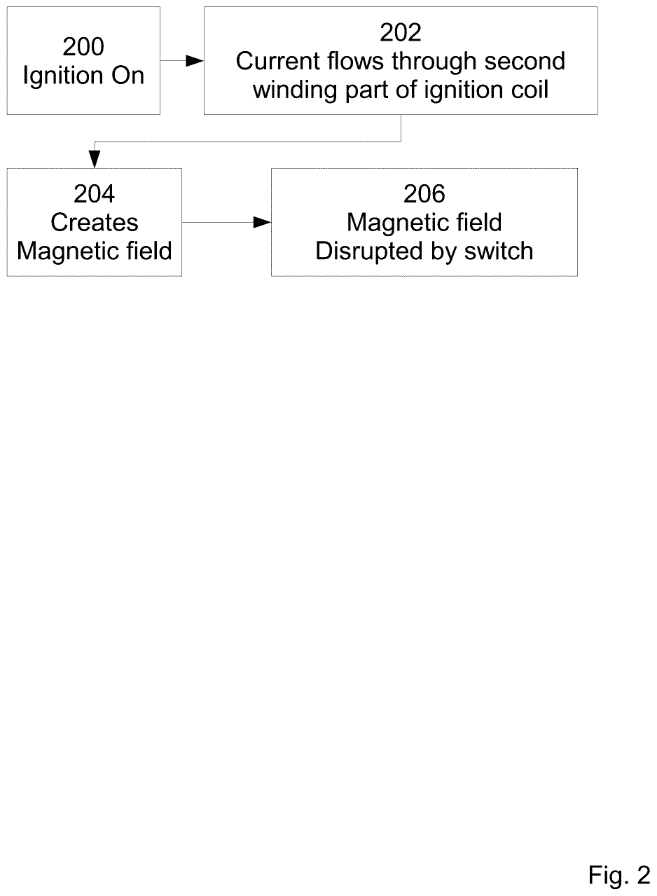

More specifically, as shown in FIG. 2, current from the battery (when the ignition is on the ON position 200) flows through the primary winding part of the ignition coil 202, creating a magnetic field 204 (which is further enhanced by the ignition coil's iron core). This magnetic field is disrupted when a switch in the circuit is activated 206.

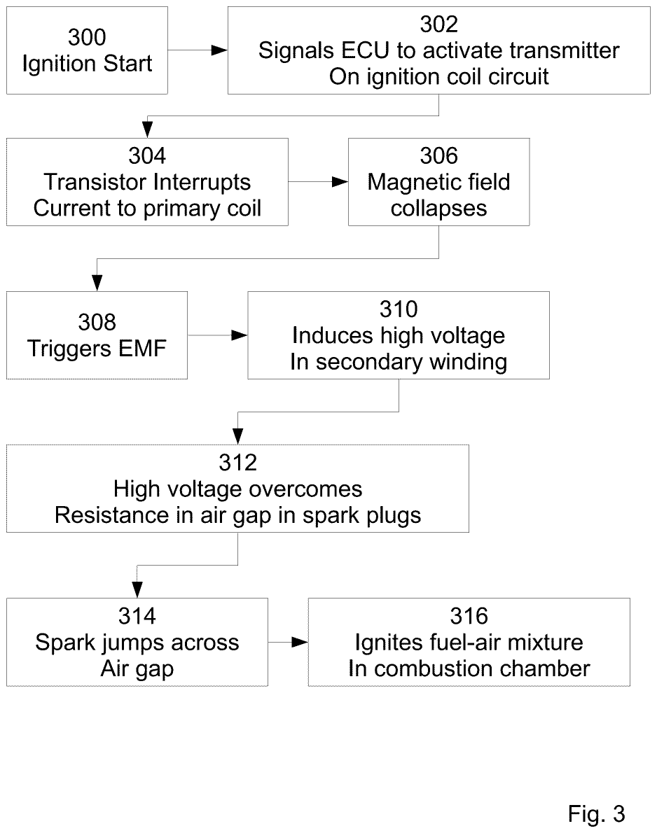

As shown in FIG. 3, changing the ignition switch to the START position 300 signals the engine control unit (ECU) to activate a transistor disposed on the ignition coil circuit 302. The transistor, in turn, interrupts the current to the primary coil 304, thereby causing a collapse of the magnetic field 306—this sudden collapse triggers an electromotive force (EMF) 308, which induces a high voltage in the secondary winding part of the ignition coil 310. This high voltage in turn overcomes the resistance in the air gap in the spark plug 312, allowing a spark to jump across the air gap 314 and ignite the fuel-air (combustion) mixture in the combustion chamber 316. Thus, the spark leads to ignition, which then leads to combustion.

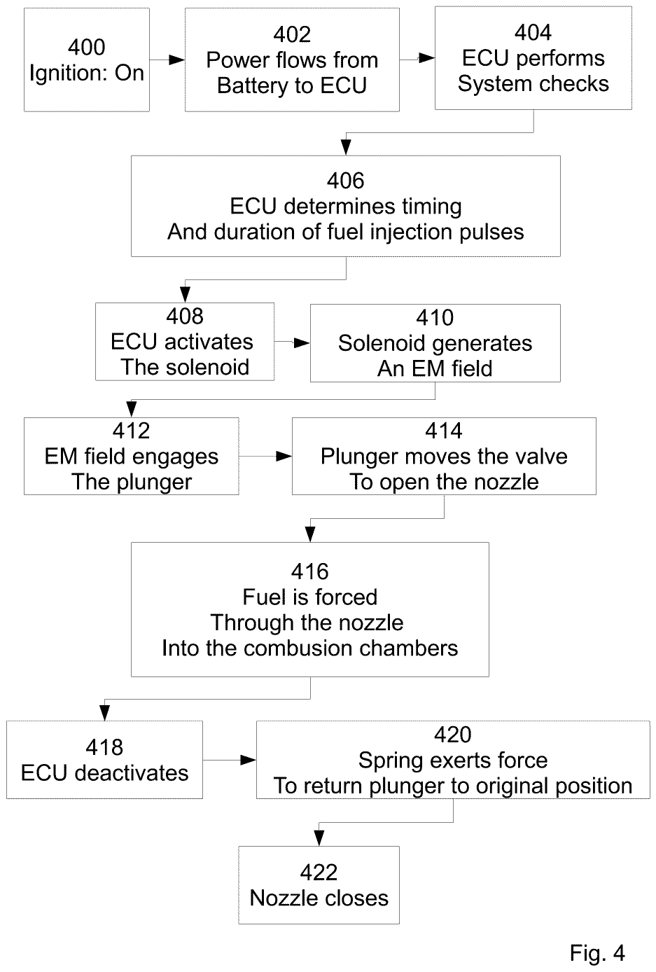

As shown in FIG. 4, when the ignition switch is changed to the ON position 400, several circuits are closed, enabling power to flow from the battery to the ECU 402. Once powered, the ECU performs a series of system checks 404 by analyzing various vehicle and engine sensors, including the mass air flow (MAF) sensor; oxygen sensors, crankshaft and camshaft position sensors, a throttle position sensor, an engine coolant temperature sensor, and manifold absolute pressure (MAP) sensor. Based on the sensor data, the ECU determines the timing and duration of the fuel injection pulses 406 in order to optimize the combustion efficiency throughout the engine cycle. When the ECU activates (i.e., energizes) the solenoid 408 via an electrical signal, the energized solenoid generates an electromagnetic field 410, which engages the plunger 412. Upon engagement, the plunger moves the valve to open the nozzle 414. Fuel, pressurized by the fuel pump, is then forced through the nozzle into the combustion chambers 416. When the ECU deactivates (i.e., de-energizes) the solenoid 418, the spring exerts a force to return the plunger to its original position 420, thereby closing the nozzle 422.

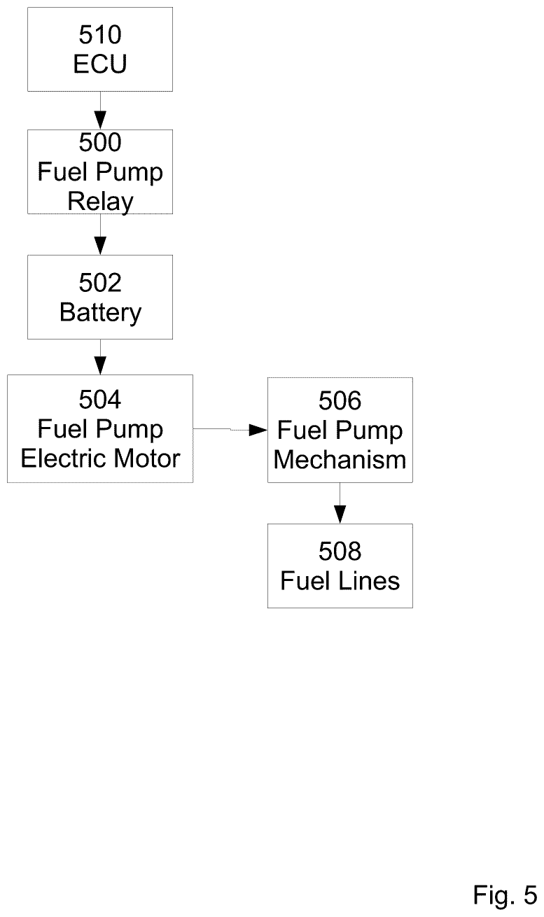

The power to the fuel pumps is controlled by a fuel pump relay. Specifically, as shown in FIG. 5, the fuel pump relay 500 enables or disables the flow of power from the battery 502—at least initially—to the fuel pump's electric motor 504, which in turn drives the fuel pump's pump mechanism 504 (e.g., a turbine, rotor, or diaphragm) responsible for physically pumping 506 the fuel through the fuel lines 508 toward the engine. The fuel pump relay is itself controlled by the ECU 510. In some systems, the ECU can control the speed of the fuel pump by varying the power supplied to it.

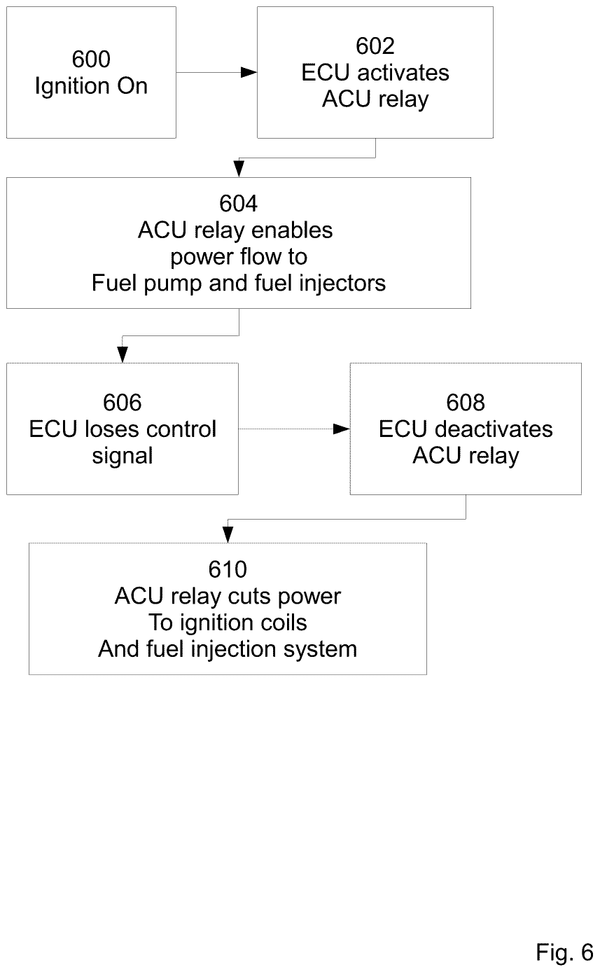

Initially, as shown in FIG. 6, when the ignition is on the ON position 600, the ECU activates the ASD relay 602 (via a resistor within the ASD relay circuit), which then allows power to be supplied to the fuel pump and fuel injectors 604. The ASD relay continues to enable the power supply so long as the ECU is receiving signals that the engine is running properly. If the ECU loses signal from 606, for example, the crankshaft position sensor within the engine, the ECU deactivates the ASD relay 608, which then cuts power to the ignition coils and the fuel injection system 610.

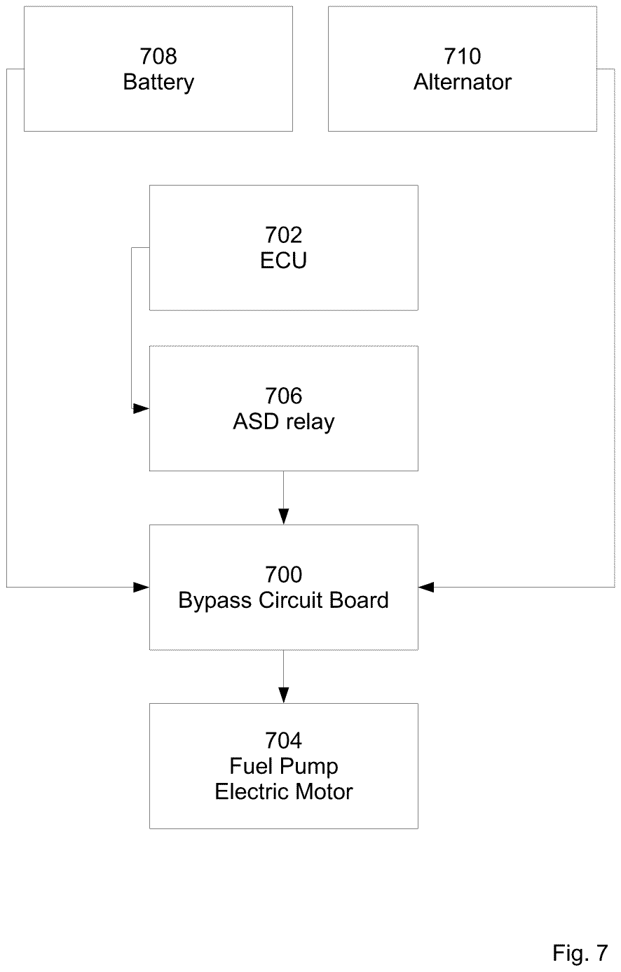

As shown in FIG. 7, power through the bypass circuit board is controlled by the ASD relay 706, which actively enables the flow of power and also serves as a power cutoff device in response to signals from the ECU 708. The ASD relay and the bypass circuit board act as intermediaries 700 through which power from the battery 708 or alternator 710 is conveyed to the fuel pump's electric motor 704, however the ASD relay serves as a prior intermediary to the bypass circuit board.

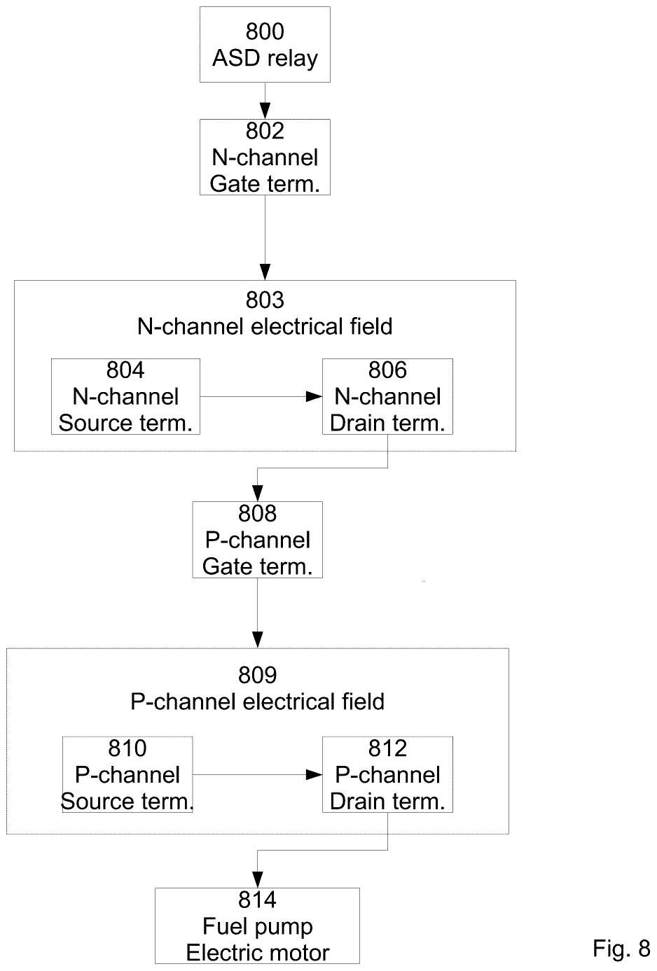

As shown in FIG. 8, the ASD relay 800 is connected to the N-channel MOSFET via the N-channel gate terminal 802. When the ASD relay provides a voltage signal (typically a positive voltage relative to the source terminal), it activates the N-channel MOSFET. This activation allows current, which consists of negative charge carriers (electrons), to flow from the N-channel source terminal 804 to the N-channel drain terminal 806. While electrons flow from source to drain, the conventional current direction is considered to be from drain to source. The N-channel gate terminal induces this current flow by modulating the electric field 803 in the channel between the source and drain terminals, enabling current flow when a sufficient gate-to-source voltage (VGSV_{GS}VGS) is applied.

The N-channel MOSFET circuit then applies a lower voltage (relative to the P-channel source) to the P-channel MOSFET gate terminal 808. The P-channel gate terminal induces current flow in the P-channel MOSFET circuit by modulating the electric field 809 in the channel between the P-channel source 810 and drain terminals 812. This action enables positive charge carrier current (holes) to flow from the P-channel source terminal to the P-channel drain terminal. This current is used to power the fuel pump electric motor 814.

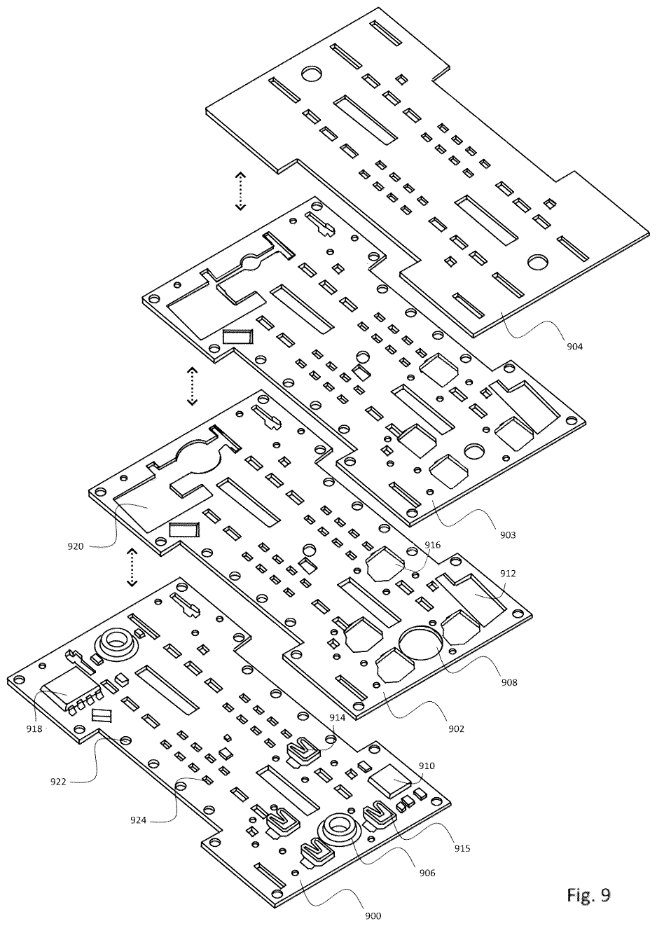

As shown in FIG. 9, the bypass circuit board may comprise a series of printed circuit boards (PCBs). Specifically, the bypass circuit board may comprise four separate PCBs, with each PCB having a dedicated set of parts and intended for a particular, mutually beneficial purpose. The PCB's may include MID 1 902, MID 2 903, and TOP PCB 904, which are not in direct contact with the bottommost PCB 900. Having a plurality of PCBs helps isolate circuits to prevent electromagnetic interference, thereby enhancing the performance of the sensitive on-board components, damper vibration shock, distribute components to better manage heat dissipation and prevent overheating, facilitate repair and maintenance, optimize space, and reduce manufacturing costs. Circuit components include mosfets 918 and 910, and positive 915 and negative 914 current ports for the battery and/or alternator. Circuit housing and structure may include mosfet housing 920 and 912, current port housing 916, and mounting bosses 906 attached to vehicular components. The mounting bosses may pass through the mounting housing 908 of the upper three PCBs. Other circuit board features may include via-to-pad mounting 922 and vents 924.

The circuit is designed to manage the power supply to a vehicle's fuel pump while bypasses various fueses and relays. At the heart of the circuit is a N-channel MOSFET (Q1) that acts as the main switch controlling the flow of current to the fuel pump. When activated, this MOSFET allows current to pass directly from the vehicle's power supply (B+) to the fuel pump, effectively replacing the traditional relay-based power routing. The MOSFET is controlled by a gate driver (Q2), which ensures that the MOSFET switches on and off quickly and efficiently based on signals from the Automatic Shutdown Relay (ASD) or the Engine Control Unit (ECU).

The circuit includes diodes (D1 and D2) that protect against voltage spikes, which are common in automotive environments, and a capacitor (C1) that smooths out any fluctuations in the power supply, ensuring stable operation. Resistors in the circuit serve various roles, such as pulling down the MOSFET gate to prevent accidental activation when the control signal is inactive and limiting inrush current to reduce noise during switching.

The ASD signal plays a crucial role in this circuit by providing the control input to the gate driver. When the ASD signal indicates that the engine is running properly, it enables the gate driver to activate the MOSFET, allowing current to flow to the fuel pump. This system bypasses the traditional relay and fuse setup, instead using solid-state components for greater reliability. However, the system still relies on the ASD relay for safety, ensuring that power to the fuel pump is only supplied when it is safe to do so, based on feedback from the ECU. This integration of solid-state technology into the vehicle's power management system reduces the potential for mechanical failure and enhances overall reliability.

The printed circuit board is a central component of the bypass circuit system designed to manage the power supply to a vehicle's fuel pump, as described in the disclosure. The PCB includes distinct connections for the positive and negative power supplies, which are fed from the vehicle's battery or alternator. These connections ensure that the board receives the correct polarity and manages the distribution of power to the various components mounted on the board.

The layout of the PCB is carefully designed to route electrical signals and power efficiently across the board, with traces connecting the power inputs to other key components like MOSFETs, gate drivers, and protective elements such as diodes and resistors. These components work together to control the flow of power to the fuel pump, responding to signals from the Automatic Shutdown Relay (ASD) and the Engine Control Unit (ECU). The board's design also includes mounting points, which allow it to be securely installed within the vehicle, likely in a location protected from vibrations and environmental factors.

This PCB integrates into the vehicle's existing electrical system, replacing the mechanical relays and fuses traditionally used to control the fuel pump. By doing so, it enhances the reliability and efficiency of the fuel pump's power management. The board's solid-state design allows it to handle power more consistently and with better protection against overcurrent and voltage spikes, all while being controlled by the ASD relay and ECU to ensure safe and proper operation of the vehicle's fuel system.

1. A vehicular bypass circuit board for bypassing a fuel pump relay, fuel pump relay fuse, and fuel pump fuse, comprising:
a. a plurality of printed circuit boards,
b. an automatic switch configured to route power flow directly to a fuel pump's electric motor based on control signals received from an automatic shutdown relay;
c. with the automatic switch being connected to and toggled by the automatic shutdown relay,
i. wherein the automatic shutdown relay is configured to receive engine control unit signals;
ii. wherein the automatic shutdown relay enables or disables power flow through the bypass circuit board to the fuel pump's electric motor in response to engine control unit signals.

2. The vehicular bypass circuit board of claim 1, with the plurality of printed circuit boards comprising a plurality of MOSFETS and circuits printed on boards, with the circuits arranged on separate boards of the plurality of printed circuit boards in order to isolate circuits to reduce electromagnetic interference and manage heat dissipation between the circuits.

3. The vehicular bypass circuit board of claim 1, additionally comprising a mounting mechanism, with the mounting mechanism configured to securely fix the plurality of printed circuit boards within the vehicle to ensure stability and reduce vibration-related damage.

4. The vehicular bypass circuit board of claim 3, with the mounting mechanism being fitting holes or mounting bosses.

5. The vehicular bypass circuit board of claim 2, with a first sub-set of the plurality of printed circuit boards not being in direct contact with a second sub-set of the plurality of printed circuit boards.

6. The vehicular bypass circuit board of claim 1, with the vehicular bypass circuit board being powered by the battery or alternator.

7. The vehicular bypass circuit board of claim 1, with the vehicular bypass circuit board conveying power from the battery or alternator.

8. The vehicular bypass circuit board of claim 1, with the vehicular bypass circuit board configured to not receive power when ignition is in an ACC position.

9. The vehicular bypass circuit board of claim 1, with the vehicular bypass circuit board configured to not transmit power to the fuel pump when ignition is in an ACC position.

10. The vehicular bypass circuit board of claim 1, additionally comprising a grounding mechanism, with the grounding mechanism configured to ensure the bypass circuit board is properly grounded to prevent electrical interference and enhance circuit stability.

11. The vehicular bypass circuit board of claim 10, with the grounding mechanism being a grounding wire or a ground plane connected to a vehicle chassis.

12. The vehicular bypass circuit board of claim 1, additionally comprising a protective enclosure surrounding the plurality of printed circuit boards for providing protection against environmental factors.

13. The vehicular bypass circuit board of claim 12, with the environmental factors being dust, debris, moisture, and heat.

14. The vehicular bypass circuit board of claim 2, with the MOSFETS forming the automatic switch.

15. The vehicular bypass circuit board of claim 2, with the MOSFETS being a combination of N-channel and P-channel MOSFETs, wherein the N-channel MOSFETs are utilized for low-side switching and the P-channel MOSFETs are utilized for high-side switching.

16. A method of bypassing a fuel pump relay, fuel pump relay fuse, and a fuel pump fuse, comprising the step of installing a vehicular bypass circuit board, the vehicular bypass circuit board comprising:
a. a plurality of printed circuit boards;
b. an automatic switch configured to route power flow directly to a fuel pump electric motor based on control signals received from an automatic shutdown relay;
c. with the automatic switch being connected to and toggled by the automatic shutdown relay in response to signals received from the engine control unit;
d. with the vehicular bypass circuit board configured to not transmit power to the fuel pump when ignition is in an ACC position.

17. The method of claim 1, with the vehicular bypass circuit board being powered by the battery or alternator.

18. The method of claim 1, with the vehicular bypass circuit board conveying power from the battery or alternator to the fuel pump electric motor.

19. A vehicular bypass circuit board for powering a vehicular fuel pump electric motor, comprising:
a. a plurality of printed circuit boards,
b. an automatic switch configured to route power flow directly to the fuel pump electric motor based on control signals received from an automatic shutdown relay;
c. with the automatic switch being connected to and toggled by the automatic shutdown relay in response to signals received from the engine control unit.

20. The vehicular bypass circuit board of claim 19, configured to bypass a vehicular fuel pump relay, a vehicular fuel pump relay fuse, and a vehicular fuel pump fuse.
